(19) United States
(12) Patent Application Publication
(10) Pub. No.: US 2020/0313093 A1
(43) Pub. Date: Oct. 1, 2020

(54) Method for Manufacturing Perovskite Solar Cells and Multijunction Photovoltaics

(71) Applicant: Brown University, Providence, RI (US)

(72) Inventors: Nitin P. Padture, Providence, RI (US); Yuanyuan Zhou, Providence, RI (US)

(21) Appl. No.: 16/303,197

(22) PCT Filed: Apr. 28, 2017
(86) PCT No.: PCT/US17/30050

§ 371 Date: Nov. 20, 2018

Related U.S. Application Data
(60) Provisional application No. 62/339,315, filed on May 20, 2016.

(51) Int. Cl. H01L 51/00; H01L 51/42; H01L 51/44

(52) U.S. Cl. CPC H01L 51/0024; H01L 51/0032; H01L 51/442; H01L 51/4213

(57) ABSTRACT

A laminated structure is prepared by providing a first substrate having a n-type oxide layer on a first surface thereof and a second substrate having a p-type oxide layer on a first surface thereof. The first surface of the first substrate, the first surface of the second substrate, or both has a liquid halide layer thereon. The first substrate is pressed into contact with the second substrate such that the first surface of the first substrate contacts the first surface of the second substrate. The halide layer is then solidified to form the laminated structure.

### RELATED APPLICATION DATA

This application claims priority to U.S. Provisional Patent Application No. 62/339,315, filed on May 20, 2016 and is hereby incorporated herein by reference in its entirety for all purposes.

### BACKGROUND

The field of thin-film photovoltaics includes perovskite solar cells that use hybrid perovskites as the light absorber. Methylammonium (M4) lead triiodide (CH₃NH₃PbI₃ or MAPbI₃) is an exemplary perovskite that has been used in solar cells. See, H. J. Snaith, J. Phys. Chem. Lett. 4, 3623-3630 (2013); M. D. McGhee, Nature 501, 323-325 (2013); M. Grätzel, Nature Mater. 13, 838-842 (2014) and H. S. Jung, N.-G. Park, Small DOI: 10.1002/sm11.201402767 (2014) in press. MAPbI₃ possesses a combination of desirable properties, including favorable direct band gap (1.50 to 1.55 eV), large absorption coefficient in the visible spectrum, high carrier mobilities and long carrier-diffusion lengths for both electrons and holes. See G. Xing, N. Mathews, S. Sun, S. S. Lim, Y. M. Lam, M. Gratzel, S. Mhaisalkar, T. C. Sum, Science 342, 344-347 (2013); S. D. Stranks, G. E. Eperon, G. Grancini, C. Menelaou, M. J. P. Alcocer, T. Leijtens, L. M. Herz, A. Petrozza, H. J. Snaith, Science 342, 341-344 (2013). This has resulted in MAPbI₃-based solar cells with power conversion efficiencies exceeding 22% (see world wide website nrel.gov/ncpv/images/efficiency_chart.jpg as of May 15, 2016) compared to earlier results. See A. Kojima, K. Teshima, Y. Shirai, T. Miyasaka, J. Am. Chem. Soc. 131, 6050-6051 (2009).

Perovskite solar cells typically contain several layers, including transparent substrate, transparent-conducting oxide (TCO) bottom electrode, electron-transport layer (n-type ETL), mesoscopic oxide/perovskite composite layer (optional), planar perovskite layer, hole-transport layer (p-type HTL), and top metal electrode. Typically, the ETL and the mesoscopic oxide is an n-type oxide (TiO₂ or ZnO or similar), which requires higher temperature processing. The deposition of these layers is conducted first, before the deposition of the perovskite to allow this high-temperature processing. After the perovskite is deposited, there are severe limitations on the deposition of the p-type HTL so as not to damage the perovskite layer. This includes using lower-temperature processing and the use of only those solvents that do not damage the perovskite. Thus, typically the HTL is limited to p-type polymers (e.g. PTAA) or organic molecules (e.g. spiro-OMeTAD). The metal electrode can be deposited at near-room temperature. In the case of inverted perovskite solar cells, an organic HTL (e.g. PEDOT:PSS) is typically used on the TCO-coated glass substrate. This is then coated with a planar perovskite layer, followed by an organic ETL (e.g. PCBM), and a metal electrode layer. In the case of the inverted solar cells, the deposition of all the layers occurs at low temperatures (<150° C.). However, the organic top layer in both the regular and inverted embodiments makes both types of solar cells susceptible to attack by moisture in the ambient. For semitransparent solar cells, the top electrode also needs to be transparent, which can be difficult to deposit at low temperatures.

There remains a need for improved manufacturing techniques, especially processes that would allow the two halves of solar cells to be fabricated separately before the perovskite layer is deposited. This would allow for the use of higher processing temperatures, thereby expanding the choice of HTL, ETL, and electrode materials. For example, this will also allow the use of mesoporous oxide as HTL for more efficient charge collection and prevent the ingress of moisture through the HTL. Also, this will allow the use of other top electrodes including less expensive metals (e.g., Ni) or glass coated with TCO.

### SUMMARY

Embodiments of the present disclosure relate in general to methods for making a laminated structure and, more particularly a solar cell. The disclosure provides a method of bonding an n-type oxide layer to a p-type oxide layer including compressing the n-type oxide layer and the p-type oxide layer having a liquid halide layer therebetween, and solidifying the liquid halide layer to bond the n-type oxide layer to the p-type oxide layer.

According to one aspect, a laminated structure is prepared by providing a first substrate having a n-type oxide layer on a first surface thereof and a second substrate having a p-type oxide layer on a first surface thereof. The first surface of the first substrate, the first surface of the second substrate, or both has a liquid halide layer thereon. The first substrate is pressed into contact with the second substrate such that the first surface of the first substrate contacts the first surface of the second substrate. The halide layer is then solidified to form the laminated structure.

In some aspects, the halide layer is liquefied by contacting the halide layer with an alkylamine gas. After the first substrate and the second substrate are pressed into contact with each other, the alkylamine gas is removed, whereby the halide layer solidifies to form the laminated structure.

In some aspects, the two portions (e.g., top and bottom halves) of solar cells may be fabricated separately before the halide layer is deposited. This advantageously allows for the use of higher processing temperatures, which in turn expands the choice of HTL, ETL, and electrode materials. A mesoporous oxide may be used as HTL for more efficient charge collection and for preventing the ingress of moisture through the HTL. This further allows for top electrodes which include less expensive metals (e.g., Ni) or glass coated with TCO.

Further features and advantages of certain embodiments of the present disclosure will become more fully apparent in the following description of the embodiments and drawings thereof, and from the claims.

### BRIEF DESCRIPTION OF THE DRAWINGS

The patent or application file contains at least one drawing executed in color. Copies of this patent or patent application publication with color drawing(s) will be provided by the Office upon request and payment of the necessary fee. The foregoing and other features and advantages of the present invention will be more fully understood from the following detailed description of illustrative embodiments taken in conjunction with the accompanying drawings in which:

FIG. 1A-1E schematically illustrate a process of manufacturing a solar cell in accordance with certain aspects of the present disclosure.

FIG. 2A is a SEM image of a raw MAPbI₃ perovskite film prepared using a conventional one-step method.

FIG. 2B is a SEM image showing that following treatment with methylamine gas, the dendrite-like crystals and the voids have disappeared, resulting in a dense, smooth film.

FIG. 2C is an AFM topographical image of the raw MAPbI₃ perovskite film showing root mean square (RMS) roughness of approximately 153 nm over an 18×18 mm² area.

FIG. 2D shows the AFM topographical image of the healed film, with a RMS roughness of about 6 nm.

FIG. 3A shows XRD patterns of raw MAPbI₃ perovskite film, MAPbI₃.xCH₃NH₂ intermediate film, and healed MAPbI₃ perovskite film on compact TiO₂-coated FTO glass substrates.

FIG. 3B shows the XRD intensity from the rough and the healed MAPbI₃ perovskite films for the 110 reflection under identical measurement conditions.

FIG. 3C shows ultraviolet-visible (UV/Vis) optical absorption spectra of MAPbI₃ perovskite with an absorption edge at approximately 780 nm.

FIGS. 4A and 4B are cross-sectional SEM images of the PSCs with raw and healed MAPbI₃ perovskite films, respectively.

FIG. 4C shows the increased current-density (J)-voltage (V) responses in performance parameters as the result of improved film morphology.

FIG. 4D is a graph showing current density values for raw MAPbI₃ perovskite films and healed MAPbI₃ perovskite films.

### DETAILED DESCRIPTION

Perovskite solar cells may be manufactured using a variety of substrates known to those of skill in the art as being useful in the manufacture of solar cells. Substrates often include a polymer, glass, ceramic, metal, or combination thereof. Substrates may be of any three dimensional configuration as desired. In some aspects, a substrate has a planar configuration.

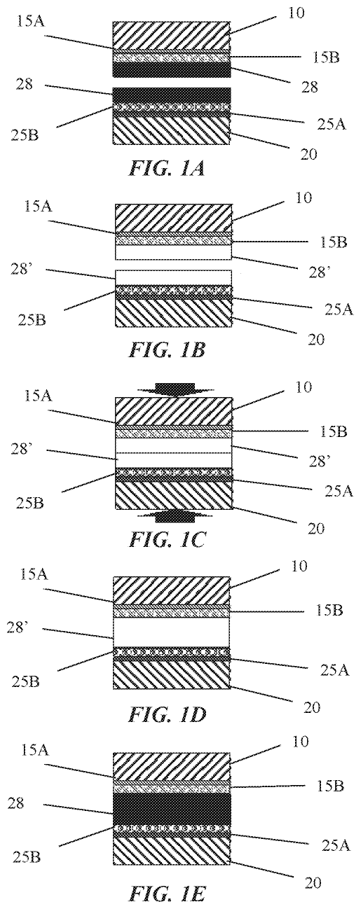

One suitable process for manufacturing a perovskite solar cell is schematically illustrated in FIGS. 1A-1E. With reference to FIG. 1A, a first (e.g., bottom) portion of the solar cell may be fabricated using conventional methods. A dense oxide electron-transport layer (ETL) 25A is deposited onto a first surface of a substrate 20. The substrate 20 may be, for example, a transparent-conducting oxide (TCO)-coated glass substrate. A variety of techniques may be used for depositing the ETL 25A, such as solution processing or spray pyrolysis, e.g., at 300-500° C. The ETL 25A may be, for example, TiO₂ or another suitable n-type oxide. The ETL 25A typically has a thickness ranging from about 10 to about 30 nm. Optionally, a mesoporous oxide layer 25B is then deposited over the ETL 25A. The mesoporous oxide layer 25B may be applied using any suitable technique, such as by depositing oxide nanoparticles in the form of paste or colloidal solution, followed by a sintering heat-treatment, e.g., at a temperature of about 300 to about 500° C. The mesoporous oxide layer 25B typically has a thickness ranging from about 50 to about 200 nm and may be TiO₂ or another suitable n-type oxide.

A second (e.g., top) portion of the solar cell may be prepared using a suitable substrate 10, such as a metal having a work function <−5.2 eV or a TCO-coated glass substrate. A hole-transport layer (p-type HTL) 15A is deposited onto a first surface of the substrate 10. The HTL 15A may be depositing by any suitable technique, such as solution processing or spray pyrolysis, e.g., at a temperature of about 300 to about 500° C. The HTL 15A may be, for example, NiO or otherp-type oxide. Typically the HTL 15A has a thickness of about 10 to about 30 nm. Optionally, a mesoporous oxide layer 15B is deposited over the HTL 15A. The mesoporous oxide layer 15B typically has a thickness ranging from about 50 to about 200 nm. The mesoporous oxide layer 15B may be applied via deposition of oxide (NiO or other p-type oxide) nanoparticles (paste or colloidal solution), followed by sintering heat-treatment, e.g., at a temperature of about 300 to about 500° C.

A halide layer 28 may be then deposited on either or both portions of the solar cell. FIG. 1A shows an example in which a halide layer 28A is applied onto the respective mesoporous oxide layers 15B and 25B of each portion. A variety of techniques may be used to deposit the halide layer 28, such as one-step or two-step solution-deposition methods or variations thereof, or a vapor-based method. The halide layer 28 typically has a thickness of about 200 to about 500 nm.

In some aspects of the present disclosure, the halide is a perovskite or a hybrid perovskite. Perovskites and hybrid perovskites and the three-dimensional or two-dimensional crystal structures they form are known to those of skill in the art and are extensively described in Cheng, et al., CrystEngComm, 2010, 12, 2646-2662 hereby incorporated by reference in its entirety.

The halide may be an organometallic halide represented by the formula RMeₙX_{y} wherein Me is Cu, Co, Ni, Fe, Mn, Pd, Cd, Sn, Pb, Ge, Eu or Yb; X is one or more of I, Br, Cl; y is 3 or (3n+1); n is 1, 2, 3, 4, 5; R is an organic group, CH₃NH₃, NH₃CH═CH₂, Cs, (R′—NH₃)₂, (NH₃—R′—NH₃)₂ or (R′—NH₃)₂R₍ₙ₋₁₎; and R′ is alkyl, C₁ to C₄ alkyl or C₆H₅C₂H₄; with the proviso that when y is 3, n is 1, Me is Pb, Sn, Ge, Eu or Yb and R is an organic group, CH₃NH₃ or NH₃CH═CH₂, or Cs, and further with the proviso that when y is (3n+1) and n is 1, Me is Cu, Co, Ni, Fe, Mn, Pd, Cd, Sn, Pb, Ge, Eu or Yb, and R is (R′—NH₃)₂ or (NH₃—R′—NH₃)₂ and further with the proviso that when y is (3n+1) and n is 2, 3, 4, or 5, Me is Cu, Co, Ni, Fe, Mn, Pd, Cd, Sn, Pb, Ge, Eu or Yb and R is (R′—NH₃)₂R₍ₙ₋₁₎.

Other examples of organometallic halides include compounds represented by the formula RMeX₃ wherein R is an organic group or Cs, Me is Pb, Sn, Ge, Eu or Yb and X is one or more of I, Br, Cl. According to one aspect, the organic group may be CH₃NH₃ or NH₃CH═CH₂.

In some examples, the organometallic halide is of the formula CH₃NH₃PbX₃, wherein X is one or more of Cl, Br, or I. For example, the organometallic halide may be CH₃NH₃PbI₃.

Yet other examples of organometallic halides include compounds represented by the formula (R—NH₃)₂MeX₄ wherein R is alkyl or C₆H₅C₂H₄, Me is a transition metal or a rare earth metal and X is one or more of Cl, Br, or I. According to one aspect, R is C₁ to C₄ alkyl or C₆H₅C₂H₄, Me is Cu, Co, Ni, Fe, Mn, Pd, Cd, Sn, Pb, Eu or Yb and X is one or more of Cl, Br, or I.

Organometallic halides also include compounds represented by the formula (NH₃—R—NH₃)₂MeX₄ wherein R is alkyl or C₆H₅C₂H₄, Me is a transition metal or a rare earth metal and X is one or more of Cl, Br, or I. According to one aspect, R is C₁ to C₄ alkyl or C₆H₅C₂H₃, Me is Cu, Co, Ni, Fe, Mn, Pd, Cd, Sn, Pb, Eu or Yb and X is one or more of Cl, Br, or I.

Other examples of organometallic halides include compounds represented by the formula (R′NH₃)₂(R)₍ₙ₋₁₎MeₙX₍₃ₙ₊₁₎ wherein R′ is C₁ to C₄ alkyl or C₆H₅C₂H₄, R is Cs, CH₃NH₃ or NH₃CH═CH₂, Me is Cu, Co, Ni, Fe, Mn, Pd, Cd, Sn, Pb, Eu or Yb, X is one or more of Cl, Br, or I and n is 2, 3, 4, or 5.

In other aspects of the present disclosure, the halide is of the formula HMeX₃, wherein Me is a transition metal or a rare earth metal and X is one or more of Cl, Br, or I. According to one aspect, Me is Cu, Co, Ni, Fe, Mn, Pd, Cd, Sn, Pb, Eu or Yb and X is one or more of Cl, Br, or I. Examples of such halides include HPbX₃, wherein X is one or more of Cl, Br, or I.

In yet other aspects, the halide is of the formula NH₄MeX₃, wherein Me is a transition metal or a rare earth metal and X is one or more of Cl, Br, or I. According to one aspect, Me is Cu, Co, Ni, Fe, Mn, Pd, Cd, Sn, Pb, Eu or Yb and X is one or more of Cl, Br, or I. Examples of such halides include NH₄PbX₃, wherein X is one or more of Cl, Br, or I.

In some aspects, the halide may be precipitated onto the surface of a substrate forming a coating on the substrate to result in a coated substrate at a temperature between about 10° C. and 70° C., between 10° C. and 50° C., between 20° C. and 30° C., or between 18° C. and 23° C. A solvent typically is used, such as a polar solvent having a boiling point within the range of 100° C. and 300° C. Non-limiting examples of suitable solvents include dimethylformamide, dimethylsulfoxide, γ-butyrolactone, n-methyl-2-pyrrolidone, dimethylacetamide, and dimethylphosphoramide.

After formation of the halide coating on the substrate, the solvent may be removed from the coated substrate, such as by drying at room temperature or other temperature at which the solvent evaporates from the coated substrate. The temperature for solvent removal often ranges from about 18° C. to 100° C.

Next, as schematically illustrated in FIG. 1B, the halide layer(s) 28 are exposed to an alkylamine gas, such as methylamine gas (CH₃NH₂). As described more fully below, the alkylamine gas transforms the halide layer(s) 28 from a solid into a molten state 28′. The entire assembly may be placed into an enclosed chamber and exposed to the alkylamine gas, for example, or alternatively the halide layer(s) may be selectively contacted with the alkylamine gas while the other layers are not exposed to the alkylamine gas.

As an alternative to alkylamine gas, the halide layer(s) may be liquefied by other suitable techniques, such as by application of other chemical reagents, thermal treatments, etc. Suitable reagents and/or techniques for liquefying a halide layer may be selected depending on such considerations as the composition and properties of the halide layer, and will be apparent to persons skilled in the art with the aid of no more than routine experimentation.

While the halide layer(s) are in a molten state 28′, the first and second portions may be brought together with the application of light pressure, as illustrated in FIG. 1C. Typically, the first and second portions remain under the alkylamine gas atmosphere while being pressed together, yielding a single molten halide layer 28′ as illustrated in FIG. 1D. The alkylamine gas is then removed, optionally with moderate heating, which results in the crystallization of the halide layer 28. As this process is completed, the first and second portions are joined together via the recrystallized halide layer 28, as illustrated in FIG. 1E. Optionally, an electric field may be applied during the degassing process to obtain textured perovskite films.

As an alternative to exposing the halide layer(s) to alkylamine gas prior to contacting the first and second portions together, the first and second portions may be first brought into face-to-face contact with application of moderate pressure. After the first and second portions are brought into contact, the alkylamine gas is then introduced. The gas diffuses through the sides and causes the perovskite to liquefy over a period of time. After a molten state is achieved, the alkylamine gas is thereafter removed (with or without moderate heating), which results in the recrystallization of the perovskite to join the first and second portions together.

While not wanting to be bound by theory, it is believed that the conversion of solid MAPbI₃ perovskite into liquid is the result of uptake of CH₃NH₂ molecules. It is believed that the basic N atom with an electron lone pair in alkylamine molecules interacts with the PbI₆-octahedra in the layered PbI₂ structure. It is likely that CH₃NH₂ reacts in a similar way with the inorganic PbI₆-octahedra framework in MAPbI₃ perovskite, resulting in the complete collapse (see Eq. (1) below) of that structure into a liquid. Upon reduction of CH₃NH₂ gas partial pressure, CH₃NH₂ molecules are released from the liquid (see Eq. (2) below), resulting in the reconstruction of the MAPbI₃ perovskite structure. The commonality of the methyl group in MAPbI₃ and CH₃NH₂ gas may be responsible for the complete conversion and reversibility.

CH₃NH₃PbI₃(s)+xCH₃NH₂(g)→CH₃NH₃PbI₃.xCH₃NH₂(l) Eq. (1)

CH₃NH₃PbI₃.xCH₃NH₂(l)→CH₃NH₃PbI₃(s)+xCH₃NH₂(g) Eq. (2)

When larger-molecule amine gases, such as ethylamine (C₂H₅NH₂) or n-butylamine (CH₃(CH₂)₃NH₂), are introduced, the MAPbI₃ perovskite particles appear to “melt” as well, resulting in the formation of liquid phase of MAPbI₃.xC₂H₅NH₂ or MAPbI₃.xCH₃(CH₂)₃NH₂, respectively, accompanied by substantial volume expansion and surface smoothening. However, complete back-conversion into the black MAPbI₃ perovskite phase does not occur after the gas is removed. Thus, for alkyl group R other than CH₃, the reaction of CH₃NH₃I+R—NH₂→R—NH₃I+CH₃NH₂ is prone to occur, resulting in the irreversible formation of a stable non-MAPbI₃ phase. This highlights the desirability of selecting CH₃NH₂ gas when using MAPbI₃ perovskite thin films.

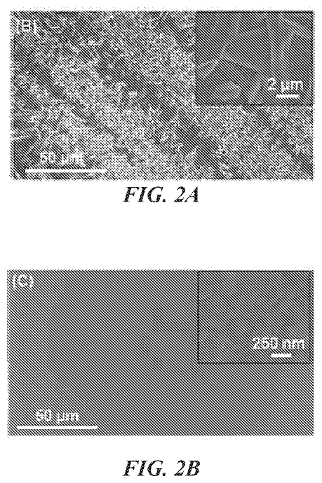

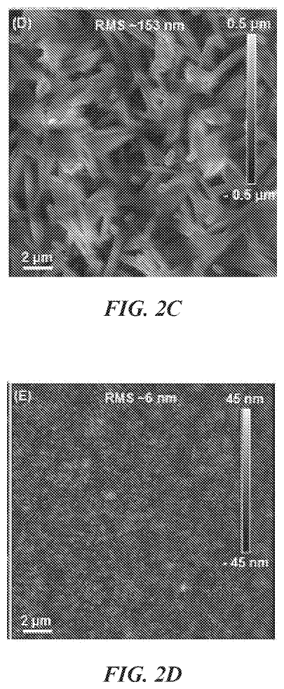

The transformation of the surface morphology of the MAPbI₃ perovskite film can be seen in the scanning electron microscope (SEM) and the atomic force microscope (AFM) images. FIG. 2A is a SEM image of the raw MAPbI₃ perovskite film (ca. 250 nm thickness) prepared using a conventional one-step method. The growth of dendrite-like MAPbI₃ perovskite crystals, and voids between them is typical of one-step-processed perovskite films using dimethylformamide (DMF) solvent. The size of the voids in the starting raw film can reach up to several micrometers. As shown in FIG. 2B, after treatment with methylamine gas, all of the dendrite-like crystals and the voids have disappeared, and a dense, smooth MAPbI₃ perovskite film has emerged in its place, which is responsible for the visual evolution of the film from dull to shiny.

FIG. 2C is an AFM topographical image of the raw MAPbI₃ perovskite film showing root mean square (RMS) roughness of approximately 153 nm over an 18×18 mm² area. In contrast, the AFM topographical image of the healed film in FIG. 2D shows a remarkably dense and smooth film, with a RMS roughness of only around 6 nm.

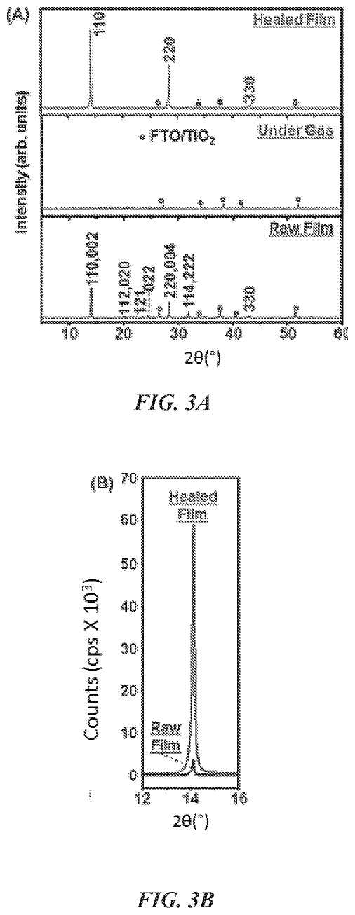

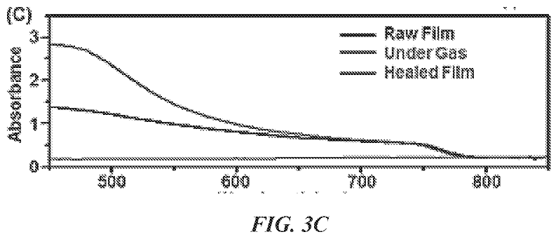

FIG. 3A shows X-ray diffraction (XRD) patterns of the raw MAPbI₃ perovskite film, MAPbI₃.xCH₃NH₂ intermediate film and healed MAPbI₃ perovskite film on compact TiO₂-coated FTO glass substrates. The XRD pattern from the raw film confirms the typical MAPbI₃ perovskite phase. The XRD pattern of the MAPbI₃.xCH₃NH₂ intermediate film under CH₃NH₂ gas shows only substrate peaks, indicative of its non-crystalline nature. After CH₃NH₂ degassing, a phase-pure, 110-textured perovskite film evolves. FIG. 3B shows the XRD intensity from the rough and the healed MAPbI₃ perovskite films for the 110 reflection under identical measurement conditions, showing a 15-fold increase in the counts after healing. This change is indicative of higher degree of crystallinity and texture in the healed film, which is highly desirable for PSCs application. FIG. 3C shows ultraviolet-visible (UV/Vis) optical absorption spectra. The raw film shows typical absorption of MAPbI₃ perovskite with an absorption edge at approximately 780 nm. The MAPbI₃.xCH₃NH₂ intermediate film shows almost no absorption, indicative of the collapse of the perovskite structure. The healed MAPbI₃ perovskite film recovers the absorption feature of the perovskite, but with significantly increased absorbance, especially in the 400-600 nm region. This is primarily due to the dense and uniform nature of the healed film, which prevents leakage of light through voids.

Upon CH₃NH₂ degassing, the weak PL signal gradually recovers from localized areas, which indicates the nucleation of MAPbI₃ perovskite. Finally, uniform, stronger PL signal is observed over the entire area in the healed MAPbI₃ perovskite film.

Exposure to CH₃NH₂ gas results in the uptake of CH₃NH₂ molecules by the raw MAPbI₃ perovskite film accompanied by a volume expansion, collapse of the perovskite structure, and the formation of a clear liquid. This occurs in a very short time because of the nanoscale of the MAPbI₃ crystals in the thin films. The liquid spreads instantaneously owing to wetting of the substrate, and forms an ultra-smooth surface. In the case of mesoscopic-oxide layer on the substrate, the liquid is likely to infiltrate readily into the mesoporous structure. Upon removal of the CH₃NH₂-gas atmosphere, the liquid releases CH₃NH₂ molecules rapidly, once again, a result of the nanoscale of the liquid MAPbI₃.xCH₃NH₂ film. This release results in volume contraction, and rebuilding of the perovskite structure by rapid nucleation and growth, ultimately resulting in an ultra-smooth and dense MAPbI₃ thin film.

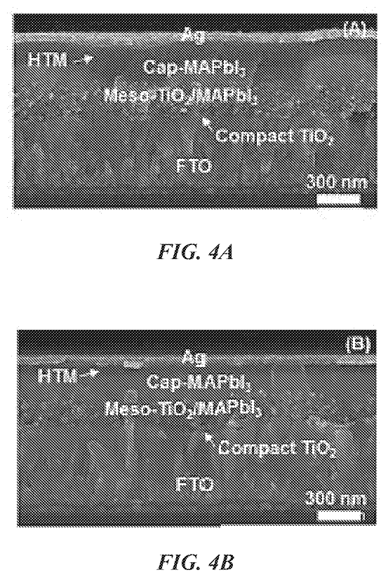

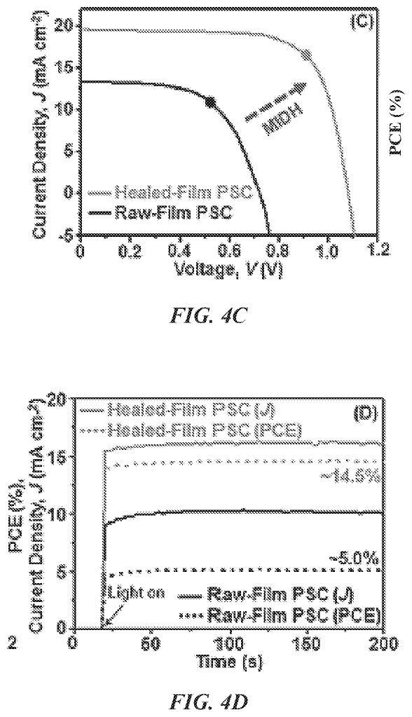

The effect on the performance of MAPbI₃-based PSCs is shown in FIGS. 4A-4D. FIGS. 4A and 4B are cross-sectional SEM images of the PSCs with raw and healed MAPbI₃ perovskite films, respectively. In the case of the healed film, the mesoporous TiO₂ layer is fully infiltrated with MAPbI₃ perovskite, and the dense MAPbI₃ perovskite “capping” layer shows smooth, uniform coverage (FIG. 4B). The current-density (J)-voltage (V) responses in FIG. 4C show obvious increase in all performance parameters (short circuit current J_{SC}: from 13.5 mAcm⁻² to 19.6 mAcm⁻²; open circuit voltage V_{OC}: from 0.72V to 1.08 V; fill factor FF: from 0.586 to 0.714). A significant increase in the overall power conversion efficiency (PCE), from 5.7% to 15.1%, is observed, which is clearly the result of the improved film morphology. The J_{SC} values are consistent with the external quantum efficiency (EQE) measurements. Since typical hysteresis still exists in both PSCs, the maximum-power-point J, which is then converted into PCE, is monitored as shown in FIG. 4D. The stabilizing PCE output at the maximum power point increases from 5.0% to 14.5%, further confirming the efficiency enhancement in PSCs.

The techniques described herein provide an unprecedented capability for the processing of high-quality, uniform MAPbI₃ perovskite films over large-areas for high-performance PSCs and beyond. The ultrafast and facile nature of the process is compatible with established scalable thin-film processing technologies. Furthermore, the concept of morphology-engineering based on reversible gas-solid interaction may be used with a broad range of halide compounds as described herein.

As will be appreciated by persons skilled in the art, a number of different layer configurations are possible between the ETL and the HTL layers, non-limiting examples of which include (i) (mesoporous n-type oxide infiltrated by perovskite)/(mesoporous p-type oxide infiltrated by perovskite), (ii) (mesoporous n-type oxide infiltrated by perovskite)/(planar perovskite)/(mesoporous p-type oxide infiltrated by perovskite), (iii) (mesoporous n-type oxide infiltrated by perovskite)/(planar perovskite), (iv) (planar perovskite)/(mesoporous p-type oxide infiltrated by perovskite), and (v) (planar perovskite).

The solar cells manufactured by the techniques described herein may have better charge extraction efficiency and low hysteresis due to better bonding between perovskite and the n-type and the p-type oxides on either side, together with better resistance to degradation by humidity due to the presence of the impervious inorganic dense ETL and HTL layers.

This approach can also be extended to create tandem or multi junction solar cells where the bottom cell is a conventional solar cell based on silicon (single-crystal or polycrystalline or amorphous) or copper-indium-gallium-selenide (CIGS) or cadmium-telluride (Cd—Te) semiconductors, and the top cell is a PSC, which is laminated to the bottom cell using the above method. Multilayers of tandem cells (multi-junction) also may be fabricated using the processes described herein. Yet other variations will be apparent to persons skilled in the art upon reading the present disclosure.

The following examples are set forth as being representative of the present invention. These examples are not to be construed as limiting the scope of the invention as these and other equivalent embodiments will be apparent in view of the present disclosure, figures and accompanying claims. All reagent grade chemicals are commercially obtained from Sigma-Aldrich (St. Louis, Mo.) unless noted otherwise.

### Example 1

### Deposition of Compact and Mesoporous Oxide Layers

Nickel acetate tetrahydrate (Ni(CH₃COO)₂.4H₂O, 99.0%) and nickel chloride hexahydrate (NiCl₂.6H₂O, 99.95%) were used as nickel sources dissolved in deionized water. The concentration of a nickel salt was 0.05 mol/L in an aqueous spray solution, and 0.1 mol/L in an alcoholic spray solution (isopropanol:H₂O=3:2, by volume). LiCl (99%) and LiNO₃ (99%) were used as dopant sources added into the spray solution, the concentration of Li ions ([Li⁺]/([Li⁺]+[Ni²⁺])) in a solution was 10 and 25 at. %. The film deposition temperature was varied from 450 C.

A mesoporous NiO solution used for spin coating was prepared by diluting slurry NiO with anhydrous ethanol in a ratio of 1:7. Slurry NiO was prepared by mixing 3 g of NiO nanopowder in 80 ml ethanol and subsequently adding with 15 g of 10 wt % ethyl cellulose (in EtOH) and 10 g of terpineol. The solution was stirred and dispersed with ultrasonic horn and concentrated with rotary evaporator for ethanol removal until 23 mbar.

A compact TiO₂ layer was deposited by spray pyrolysis at 450° C. The solution for spray pyrolysis is 0.2 M Ti (IV) bis(ethyl acetoacetato)-diisopropoxide in iso-propanal.

A mesoporous TiO₂ layer was spin-coated at 2000 rpm for 35 s from the TiO₂ paste, which consists of 5.4% TiO₂ nanoparticles and 1.6% ethyl cellulose in terpineol/ethanol (3/7 weight ratio) solution. The mesoporous layer was sintered at 450° C. for 30 min.

### Example II

### Deposition of Organometallic Halide Thin Films

Methylammonium iodide (CH₃NH₃I or MAI) was prepared using a process as described in M. M. Lee, J. Teuscher, T. Miyasaya, T. N. Murakami, H. J. Snaith, Science 338, 643-647 (2012). In a typical procedure, 20 mL methylamine (30% in ethanol) and 24 mL of hydroiodic acid (47 wt % in water) were mixed and reacted at 0° C. for 2 h while stirring under a N₂ atmosphere. After rotary evaporation, the CH₃NH₃I powder was collected and washed three times and dried in a vacuum oven.

A TiO₂ sol was prepared by mixing 10 mL titanium (IV) isopropoxide (99%) with 50 mL 2-methoxyethanol (98%) and 5 mL ethanolamine (99%) in a three-necked flask, each connected with a condenser, thermometer, and argon gas inlet/outlet. The mixed solution was heated to 80° C. for 2 h under magnetic stirring, followed by heating to 120° C. for 1 h. This two-step heating was then repeated two times to result in a viscous solution. The sol was spin-coated (4000 rpm, 45 s) on fluorine-doped tin oxide (FTO)-coated glass substrates, followed by a heat-treatment of 550° C. for 30 min in air, to deposit a 30-nm compact-TiO₂ layer.

To obtain MAPbI₃ perovskite particles, a 40 wt. % PbI₂:MAI (molar ratio 1:1) mixture was dissolved in γ-butyrolactone (GBL, 99.5%) and then heated to 108° C. on a hotplate for 2 h, forming several black MAPbI₃ perovskite particles, 2-3 mm in size, at the bottom of the container. Subsequently, the top solvent was removed by a syringe, and the crystals were rinsed in ether.

The starting raw MAPbI₃ perovskite films were deposited using the conventional one-step method. Here, a 40 wt. % PbI₂:MAI (molar ratio 1:1) solution in N,N-dimethylformamide (DMF; 99.8%) was spin coated (4000 rpm, 45 s), followed by a heat-treatment at 100° C. for 10 min.

CH₃NH₂ gas was synthesized as follows: 10 g MACl (98%) and 10 g KOH (85%) powders were sequentially dissolved in 100 mL H₂O and then heated to 60° C. The resulting gas was passed through a CaO dryer to remove any moisture. The starting raw MAPbI₃ perovskite films were placed in the CH₃NH₂ gas environment for 2-3 s at room temperature, and were then quickly removed to the ambient.

### Example III

### Material Characterization

X-ray diffraction (XRD) patterns were obtained using a X-ray diffractometer (D8 Advance, Bruker, Germany) using Cu Kα radiation, with 0.02° step and 2 s/step dwell. To collect XRD patterns from the films under gas, the films were affixed in an X-ray transparent holder with a CH₃NH₂ atmosphere. UV-vis absorption spectra of the perovskite films were recorded using spectrometer (U-4100, Hitachi, Japan). UV-vis measurements on the films under CH₃NH₂ gas were performed on samples sealed in quartz. A field-emission SEM (S-4800, Hitachi, Japan) was used to observe the top surfaces and cross-sections. AFM measurements were performed in contact mode using AFM microscope (5400, Agilent, USA). In situ PL mapping was conducted using a confocal laser scanning microscope (Fluo View™ FV1000, Olympus, Japan). The film was excited used a 515 nm laser, and images were collected using light in 700-800 nm wavelength range. All films for XRD, SEM, AFM, UV-vis and PL measurements were deposited on compact-TiO₂-coated-FTO/glass substrates for consistency. Note that partial quenching of photoluminescence via compact-TiO₂ layer may reduce the PL signal intensity but this does not affect the conclusion of experimental observations in this particular study.

The in situ optical microscopy observation of two MAPbI₃ perovskite particles was carried out using a stereomicroscope (SZX16, Olympus, Japan). These experiment were conducted by placing the MAPbI₃ particles on a glass substrate in a home-made gas chamber with transparent windows (transmittance >95%). A gas gun was used to introduce CH₃NH₂ atmosphere around the sample.

### Example IV

### Solar Cell Fabrication and Testing

FTO/glass substrates were patterned by etching with Zn powder and 1 M HCl diluted in distilled water. The etched substrates were then cleaned with ethanol, saturated KOH solution in isopropanol, and water sequentially, and then they were dried in clean dry air. A 30-nm compact-TiO₂ layer was deposited on top of the etched FTO/glass substrates using the procedure described earlier. A 250-nm mesoporous-TiO₂ layer was then deposited by spin-coating a dilute commercial TiO₂ paste (1:3 with ethanol by weight) at 4000 rpm, 45 s, followed by a sintering heat-treatment of 550° C. for 30 min in air. The MAPbI₃ perovskite layer was then deposited using the one-step method, as described earlier. A solution of spiro-MeOTAD (99%) hole-transporting material (HTM) coating was prepared by dissolving 72.3 mg of spiro-MeOTAD in 1 mL of chlorobenzene (99.8%), to which 28.8 μL of 4-tert-butyl pyridine (96%) and 17.5 μL of lithium bis(trifluoromethanesulfonyl) imide (LITSFI) solution (520 mg LITSFI (98%) in 1 mL acetonitrile (99.8%) were added. The HTM was deposited by spin-coating (3000 rpm, 30 s). Finally, a 100 nm Ag electrode was thermally-evaporated to complete the solar cells. In some cases, the MAPbI₃ perovskite layer was healed before depositing the HTM and the Ag layers. Healing was performed by exposing the one step-deposited MAPbI₃ perovskite film to CH₃NH₂ gas for 3 s at room temperature, followed by removing it to the ambient and allowing it to degas naturally. The HTM and the Ag layers were then deposited to complete the PSC assembly.

J-V characteristics of the as-fabricated PSCs were measured using a 2400 Sourcemeter (Keithley, USA) under simulated one-sun AM 1.5G 100 mW cm⁻² intensity (Oriel Sol3A Class AAA, Newport, USA), under both reverse (from V_{OC} to J_{SC}) and forward (from J_{SC} to V_{OC}) scans. The step voltage was 50 mV with a 10 ms delay time per step. The maximum-power output stability of the PSCs was measured by monitoring the J output at the maximum-power V bias (deduced from the reverse-scan J-V curves) using a procedure described by Snaith et al., J. Phys. Chem. Lett., 2014, 5, 1511-1515. The J output is converted to PCE output using the following relation: PCE={J (mA cm⁻²)×V (V))/(100 (mW cm⁻²)}. A shutter was used to switch on and off the one-sun illumination on the PSC. Typical active area of the PSCs is 0.09 cm² defined using non-reflective metal mask. External quantum efficiency (EQE) measurements were carried out on an EQE measurement setup (Newport, USA) comprising a Xe lamp, a Cornerstone™ monochromator, a current-voltage preamplifier, and a lock-in amplifier. The intensity of the one-sun AM 1.5G illumination was calibrated using a Si-reference cell certified by the National Renewable Energy Laboratory. All PSCs testing was conducted in the ambient with a relative humidity of ˜20%.

### Example V

### Alternative Manufacturing Techniques

The starting rough MAPbI₃ perovskite films were also fabricated using three other methods: (i) A 40 wt. % PbCl₂:MAI (molar ratio 1:3) solution in DMF was spin-coated (4000 rpm, 45 s), followed by a heat-treatment at 100° C. for 45 min.; (ii) A 40 wt. % PbI₂:MAI (molar ratio 1:1) solution in γ-butylacetone (GBL) was spin-coated (4000 rpm, 45 s), followed by a heat-treatment at 100° C. for 45 min. (iii) A 1 M PbI₂ solution in DMF was spin-coated (3000 rpm for 45 s), and then dipped into a MAI isopropanol solution (8 mg/mL) for 1 min. This was followed by a heat-treatment at 100° C. for 5 min.

Healing of these films with methylamine gas was conducted in the same way as described earlier. While 250-nm mesoporous TiO₂ layer (on compact-TiO₂-coated FTO/glass) substrates were used in this study, the morphology of the healed perovskite films is almost identically smooth and independent of substrate used. Other substrates that were used included plain glass, quartz, FTO/glass, and compact-TiO₂-coated FTO/glass.

For experiments with other gases, the ethylamine (C₂H₅NH₂) gas was synthesized by heating the C₂H₅NH₂ ethanol solution (30%) at 50° C., and the mixed gas that was produced was passed through CaCl₂ powder to remove the ethanol. The n-butylamine (CH₃(CH₂)₃NH₂) gas was produced directly by heating liquid CH₃(CH₂)₃NH₂ (98%) at 50° C.

It is to be understood that the embodiments of the present invention which have been described are merely illustrative of some of the applications of the principles of the present invention. Numerous modifications may be made by those skilled in the art based upon the teachings presented herein without departing from the true spirit and scope of the invention. The contents of all references, patents and published patent applications cited throughout this application are hereby incorporated by reference in their entirety for all purposes.

What is claimed is:

1. A method of making a laminated structure comprising:
providing a first substrate having a n-type oxide layer on a first surface thereof and a second substrate having a p-type oxide layer on a first surface thereof, wherein the first surface of the first substrate, the first surface of the second substrate, or both has a liquid halide layer thereon;
pressing the first substrate into contact with the second substrate such that the first surface of the first substrate contacts the first surface of the second substrate; and
solidifying the halide layer to form the laminated structure.

2. The method of claim 1 wherein the first substrate is selected from the group consisting of polymer, glass, ceramic, metal, and a combination thereof.

3. The method of claim 1 wherein the second substrate is selected from the group consisting of glass, Ni, Al, Mo, Cr, Ti, Ag, Co, Zn, and a combination thereof.

4. The method of claim 1 wherein the halide is of the formula CH₃NH₃MeX₃, wherein Me is a transition metal or a rare earth metal and X is selected from the group consisting of I, Br, Cl, and a combination thereof.

5. The method of claim 4 wherein the halide is of the formula CH₃NH₃PbI₃.

6. The method of claim 1 wherein the halide is of the formula HMeX₃, wherein Me is a transition metal or a rare earth metal and X is selected from the group consisting of I, Br, Cl, and a combination thereof.

7. The method of claim 6 wherein the halide is of the formula HPbX₃.

8. The method of claim 1 wherein the halide is of the formula NH₄MeX₃, wherein Me is a transition metal or a rare earth metal and X is selected from the group consisting of I, Br, Cl, and a combination thereof.

9. The method of claim 8 wherein the halide is of the formula NH₄PbX₃.

10. The method of claim 1 further comprising a step of liquefying the halide layer by contacting the halide layer with an alkylamine gas, wherein the halide layer is solidified by removing the alkylamine gas.

11. The method of claim 10 wherein the alkylamine gas is CH₃NH₂.

12. The method of claim 1 further comprising a step of applying the halide layer to the first substrate, the second substrate, or both by solution-deposition, vapor-deposition, or a combination thereof.

13. The method of claim 1 further comprising a step of applying the n-type oxide layer onto the first substrate by solution-deposition or spray pyrolysis.

14. The method of claim 13 wherein the n-type oxide layer has a thickness of about 10 to about 30 nm.

15. The method of claim 1 further comprising a step of applying the p-type oxide layer onto the second substrate by solution-deposition or spray pyrolysis.

16. The method of claim 15 wherein the p-type oxide layer has a thickness of about 10 to about 30 nm.

17. The method of claim 1 wherein the first substrate is pressed into contact with the second substrate prior to liquefying the halide layer.

18. The method of claim 1 wherein the halide layer is liquefied prior to pressing the first substrate into contact with the second substrate.

19. A laminated structure made by the method of claim 1.

20. A solar cell made by the method of claim 1.

21. A method of bonding an n-type oxide layer to a p-type oxide layer comprising compressing the n-type oxide layer and the p-type oxide layer having a liquid halide layer therebetween, and solidifying the liquid halide layer to bond the n-type oxide layer to the p-type oxide layer.
